(19) United States
(12) Patent Application Publication
(10) Pub. No.: US 2025/0329649 A1
(43) Pub. Date: Oct. 23, 2025

(54) SEMICONDUCTOR STRUCTURES WITH DUAL SIDE POWER DELIVERY

(71) Applicant: Taiwan Semiconductor Manufacturing Company, Ltd., Hsin-Chu (TW)

(72) Inventors: Sheng-Hsiung Wang, Hsinchu County (TW); Jiann-Tyng Tzeng, Hsinchu (TW); Chen-Ming Lee, Taoyuan County (TW); I-Wen Wu, Hsinchu City (TW); Kung-Cheng Lin, Hsinchu City (TW)

(21) Appl. No.: 18/641,058

(22) Filed: Apr. 19, 2024

(51) Int. Cl. H01L 23/528; H01L 21/285; H01L 29/06; H01L 29/40; H01L 29/417; H01L 29/423; H01L 29/45; H01L 29/66; H01L 29/775

(52) U.S. Cl. CPC H01L 23/5286; H01L 21/28518; H10D 30/014; H10D 30/43; H10D 30/6729; H10D 30/6735; H10D 62/121; H10D 64/01; H10D 64/017; H10D 64/62

(57) ABSTRACT

Semiconductor structures and methods are provided. In an embodiment, an exemplary method includes receiving a workpiece comprising a plurality of nanostructures over a substrate, a gate stack wrapping around and over the plurality of nanostructures, and a source/drain feature coupled to the plurality of nanostructures. The method also includes forming a dielectric structure over the workpiece, forming a first opening in the dielectric structure to expose the source/drain feature, forming a source/drain contact in the first opening, and forming a backside via disposed under the source/drain feature and in direct contact with the source/drain contact.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs and, for these advances to be realized, similar developments in IC processing and manufacturing are needed. For example, as technology nodes become smaller and to further reduce power consumption, besides being routed to a front side of a semiconductor device, power signals may also be routed to a back side of the semiconductor device for power and chip space optimization. Although existing structures for providing dual side power routing have been generally adequate for their intended purposes, they are not entirely satisfactory in every aspect.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flow chart of a method for forming a semiconductor structure, according to one or more aspects of the present disclosure.

FIG. 2 illustrates a fragmentary top view of an exemplary structure to undergo various stages of operations in the method of FIG. 1, according to various aspects of the present disclosure.

FIGS. 3A, 4A, 5A, 6A, 7A, 8A, 9A, 11A, 12A, 13A, 14A, 15A, 16A, and 18A illustrate fragmentary cross-sectional views of the structure taken along line A-A as shown in FIG. 2 during various fabrication stages in the method of FIG. 1, according to one or more aspects of the present disclosure.

FIGS. 3B, 4B, 5B, 6B, 7B, 8B, 9B, 11B, 12B, 13B, 14B, 15B, 16B, and 18B illustrate fragmentary cross-sectional views of the structure taken along line B-B as shown in FIG. 2 during various fabrication stages in the method of FIG. 1, according to one or more aspects of the present disclosure.

FIG. 10 illustrates a fragmentary top view of the structure shown in FIGS. 11A-11B, according to various aspects of the present disclosure.

FIGS. 11C, 12C, 13C, 14C, 15C, 16C, and 18C illustrate fragmentary cross-sectional views of the structure taken along line C-C as shown in FIG. 10 during various fabrication stages in the method of FIG. 1, according to one or more aspects of the present disclosure.

FIG. 11D illustrates a fragmentary cross-sectional view of the structure taken along line D-D as shown in FIG. 10 during various fabrication stages in the method of FIG. 1, according to one or more aspects of the present disclosure.

FIG. 19 illustrates a fragmentary top view of the structure shown in FIGS. 18A-18C, according to various aspects of the present disclosure.

FIG. 20 illustrates a fragmentary cross-sectional view of an alternative semiconductor structure, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

As integrated circuit (IC) technologies progress towards smaller technology nodes, multi-gate devices are introduced to improve gate control by increasing gate-channel coupling, reducing off-state current, and reducing short-channel effects (SCEs). A multi-gate device generally refers to a device having a gate structure, or portion thereof, disposed over more than one side of a channel region. Gate-all-around (GAA) transistors are examples of multi-gate devices that have become popular and promising candidates for high performance and low leakage applications. A gate-all-around (GAA) transistor has a gate structure that can extend, partially or fully, around a channel region to provide access to the channel region on two or more sides. The channel region of a GAA transistor may be formed from nanowires, nanosheets, other nanostructures, and/or other suitable structures. The shapes of the channel region have also given a GAA transistor alternative names such as a nanosheet transistor or a nanowire transistor.

For power and chip space optimization, power signals may be routed to both a front side and a back side of a target device (e.g., GAA transistor). In some existing technologies, to provide the power signal to the front side of the source/drain feature, a semiconductor device (e.g., GAA transistor) (hereinafter referred to as a “neighbor device”) disposed adjacent to the target device is involved during power delivery, and additional features (e.g., frontside source/drain contact and frontside source/drain via over the source/drain feature of the neighbor device, backside via under the source/drain feature of the neighbor device) are needed to connect the front side of the source/drain feature to the power signal. However, when the target device and the neighbor device both work, dual side power delivery efficiency may be impacted. Also, forming those additional features may disadvantageously induce power delivery uncertainty and affect device performance. Those additional features may also take up an undue amount of real estate in an IC chip and increase fabrication difficulty.

The present disclosure relates to semiconductor structures with dual side power delivery scheme and methods for forming the same. In an embodiment, a semiconductor structure includes a transistor and conductive features electrically connected to a source/drain (S/D) feature of the transistor for providing dual side power delivery routing. For backside power delivery routing, power signal may be routed from a back side of the source/drain feature through a backside via disposed directly under the source/drain feature. To solve the problems described above, in this present disclosure, for frontside power delivery routing, a frontside source/drain contact that is disposed over and electrically coupled to the source/drain feature is further configured to directly contact the backside via. That is, the frontside power routing is obtained without getting the neighbor device involved. A shorter route may also advantageously contribute to a reduced parasitic resistance and improved power delivery efficiency and device speed.

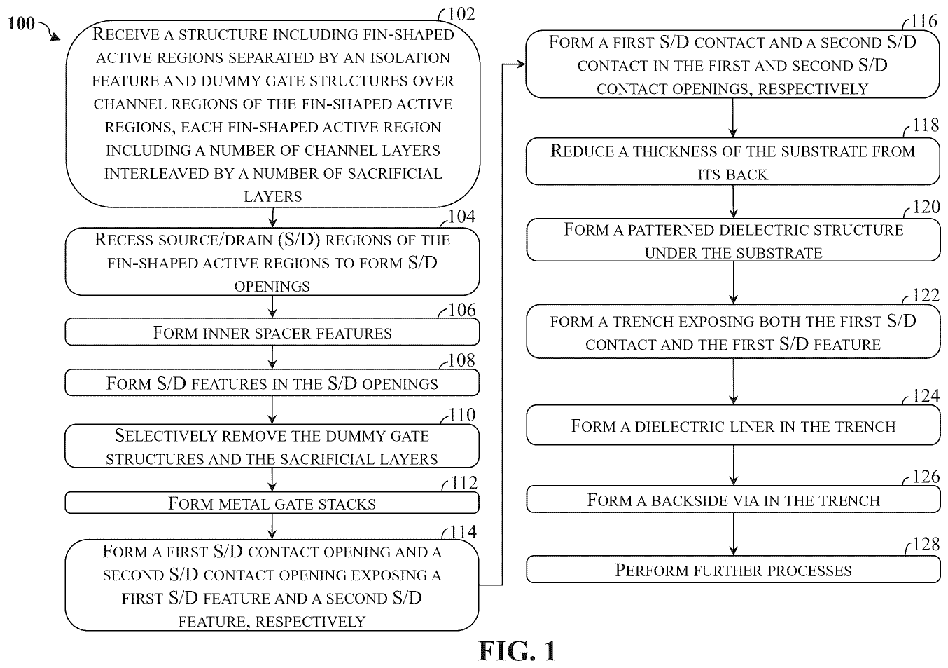

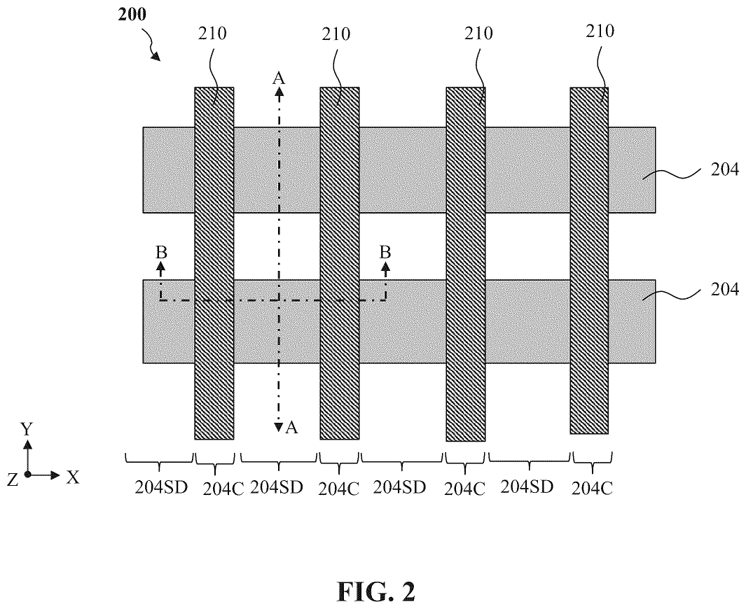

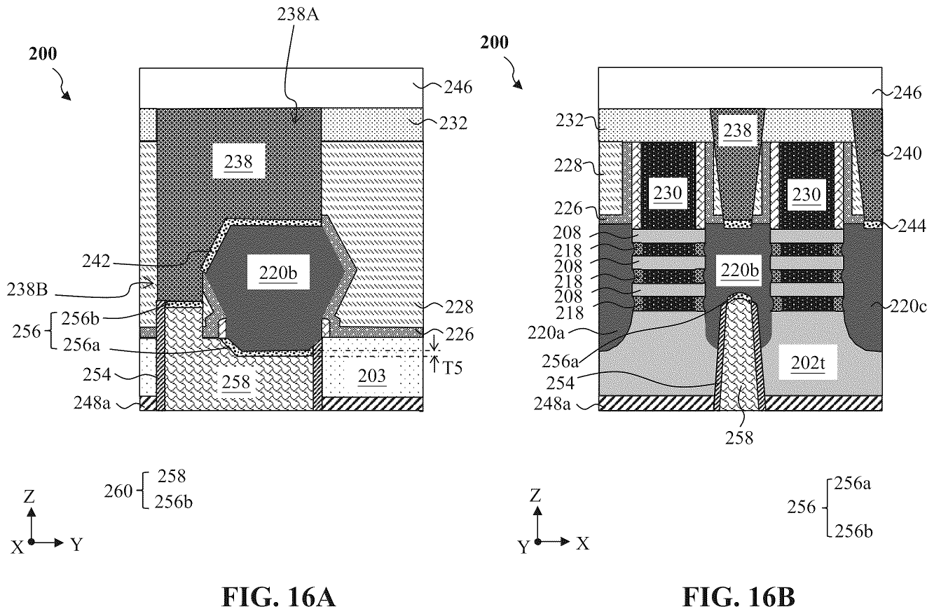

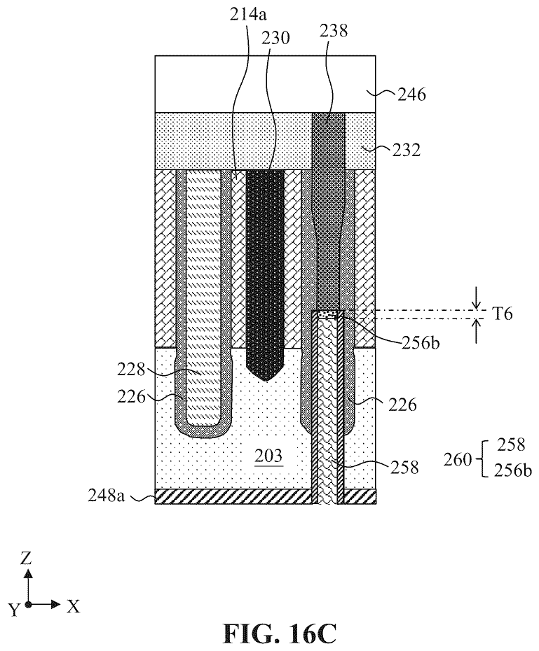

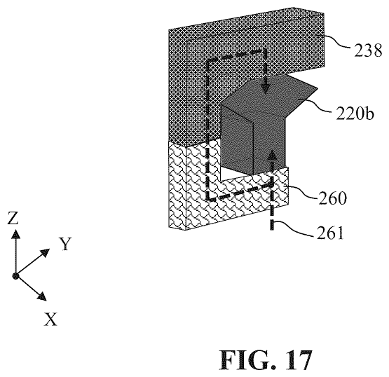

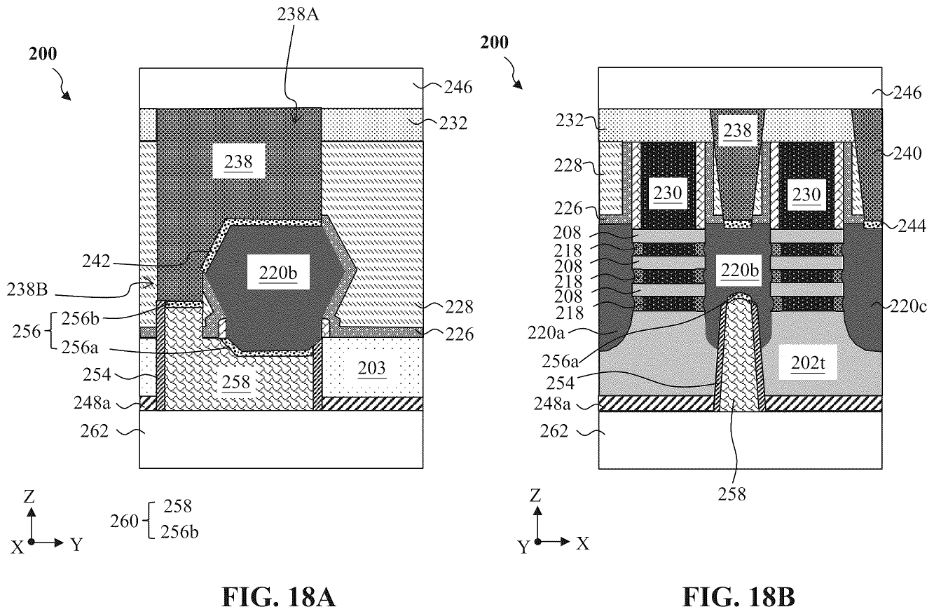

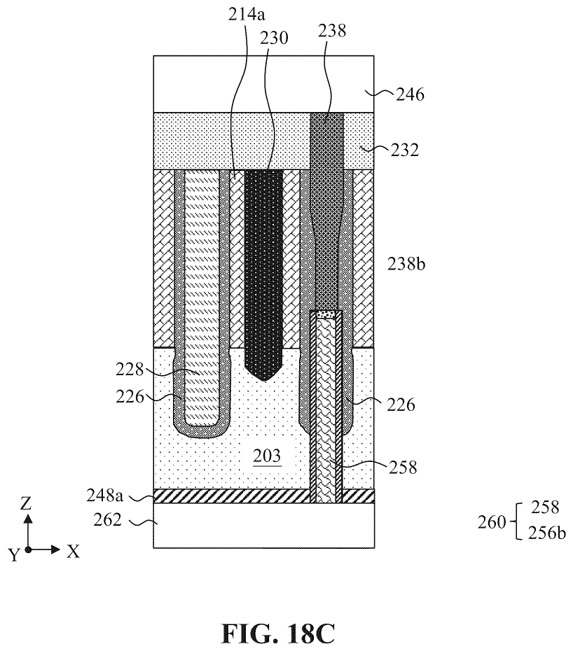

The various aspects of the present disclosure will now be described in more detail with reference to the figures. In that regard, FIG. 1 is a flowchart illustrating method 100 of forming a semiconductor structure according to embodiments of the present disclosure. Method 100 is described below in conjunction with FIGS. 2-20 which are fragmentary top/cross-sectional views of a structure 200 at different stages of fabrication according to embodiments of method 100. Method 100 is merely an example and is not intended to limit the present disclosure to what is explicitly illustrated therein. Additional steps may be provided before, during and after the method 100, and some steps described can be replaced, eliminated, or moved around for additional embodiments of the method. Not all steps are described herein in detail for reasons of simplicity. Because the structure 200 will be fabricated into a semiconductor structure upon conclusion of the fabrication processes, the structure 200 may be referred to as the semiconductor structure 200 as the context requires. For avoidance of doubts, the X, Y and Z directions in FIGS. 2-20 are perpendicular to one another and are used consistently throughout the present disclosure. Throughout the present disclosure, like reference numerals denote like features unless otherwise excepted.

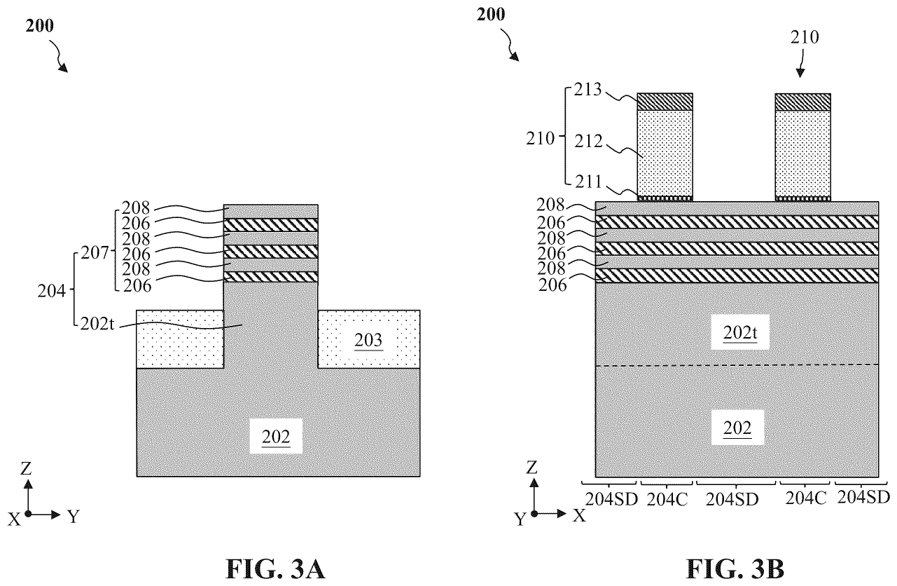

Referring to FIGS. 1, 2, and 3A-3B, method 100 includes a block 102 where a structure 200 is received. FIG. 2 depicts a fragmentary top view of a structure 200 to undergo various stages of operations in the method of FIG. 1, according to various aspects of the present disclosure. FIG. 3A illustrates a fragmentary cross-sectional view of the structure 200 taken along line A-A as shown in FIG. 2, and FIG. 3B illustrates a fragmentary cross-sectional view of the structure 200 taken along line B-B as shown in FIG. 2.

As illustrated in FIGS. 3A-3B, the structure 200 includes a substrate 202. The substrate 202 may be an elementary (single element) semiconductor, such as silicon (Si) or germanium (Ge) in a crystalline structure; a compound semiconductor, such as silicon carbide (SiC), gallium arsenic (GaAs), gallium phosphide (GaP), indium phosphide (InP), indium arsenide (InAs), and/or indium antimonide (InSb); an alloy semiconductor such as silicon germanium (SiGe), gallium arsenic phosphide (GaAsP), aluminum indium arsenide (AlInAs), aluminum gallium arsenide (AlGaAs), gallium indium arsenide (GaInAs), gallium indium phosphide (GaInP), and/or gallium indium arsenic phosphide (GaInAsP); a non-semiconductor material, such as soda-lime glass, fused silica, fused quartz, and/or calcium fluoride (CaF₂); and/or combinations thereof. In one embodiment, the substrate 202 is a silicon (Si) substrate. The substrate 202 may be uniform in composition or may include various layers, some of which may be selectively etched to form fin-shaped active regions (e.g., the fin-shaped active regions 204). The layers may have similar or different compositions, and in various embodiments, some substrate layers have non-uniform compositions to induce device strain and thereby tune device performance. Examples of layered substrates include silicon-on-insulator (SOI) substrates 202. In some such examples, a layer of the substrate 202 may include an insulator such as a semiconductor oxide, a semiconductor nitride, a semiconductor oxynitride, a semiconductor carbide, and/or other suitable insulator materials. Doped regions, such as wells, may be formed in the substrate 202.

Still referring to FIGS. 2 and 3A-3B, the structure 200 includes fin-shaped active regions 204 protruding from the substrate 202. The number of fin-shaped active regions 204 depicted in FIGS. 2 and 3A-3B is just an example, the structure 200 may include any suitable number of fin-shaped active regions. Each of the fin-shaped active regions 204 may be formed from a top portion 202t (shown in FIGS. 3A-3B) of the substrate 202 and a vertical stack 207 of alternating semiconductor layers disposed on a top surface of the substrate 202. In an embodiment, the vertical stack 207 includes a number of channel layers 208 interleaved by a number of sacrificial layers 206. Each of the channel layers 208 may include a semiconductor material such as, silicon, germanium, silicon carbide, silicon germanium, GeSn, SiGeSn, SiGeCSn, other suitable semiconductor materials, or combinations thereof, while each sacrificial layer 206 has a composition different from that of the channel layers 208. In an embodiment, each of the channel layers 208 includes silicon (Si), and each of the sacrificial layers 206 includes silicon germanium (SiGe). Although the vertical stack 207 of the depicted example includes three channel layers and three sacrificial layers, it is understood that the vertical stack 207 may include any suitable number (e.g., 2 to 10) of channel layers and any suitable number sacrificial layers. The vertical stack 207 and the top portion 202t of the substrate 202 are then patterned to form the fin-shaped active regions 204. In some embodiments, the patterned top portion 202t of the substrate 202 may be referred to as a mesa structure 202t. Each of the fin-shaped active regions 204 extends lengthwise along the X direction and is divided into channel regions 204C overlapped by dummy gate structures 210 (to be described below) and source/drain regions 204SD not overlapped by the dummy gate structures 210. Source/drain region(s) 204SD may refer to a source region or a drain region, individually or collectively dependent upon the context. Each of the channel regions 204C is disposed between two source/drain regions 204SD along the X direction.

The structure 200 also includes an isolation feature 203 (shown in FIG. 3A) formed around the fin-shaped active regions 204 to isolate one fin-shaped active region 204 from an adjacent fin-shaped active region 204. The isolation feature 203 may include shallow trench isolation (STI) feature 203. In an example process, a dielectric material is deposited over the structure 200 to fill the trenches between the fin-shaped active regions 204, thinned and planarized (e.g., by a chemical mechanical polishing (CMP) process until top surfaces of the fin-shaped active regions 204 are exposed) and further recessed or etched back by a dry etching process, a wet etching process, and/or a combination thereof to form the STI feature 203. The dielectric material may include silicon oxide, silicon oxynitride, fluorine-doped silicate glass (FSG), a low-k dielectric, combinations thereof, and/or other suitable materials and may be deposited by a CVD process, a flowable CVD (FCVD) process, spin-on coating, and/or other suitable process. The deposited dielectric material may be a single-layer structure or a multi-layer structure. In embodiments represented in FIG. 3A, upper portions of the fin-shaped active regions 204 rise above the STI feature 203 while lower portions of the fin-shaped active regions 204 remain covered or buried in the STI feature 203.

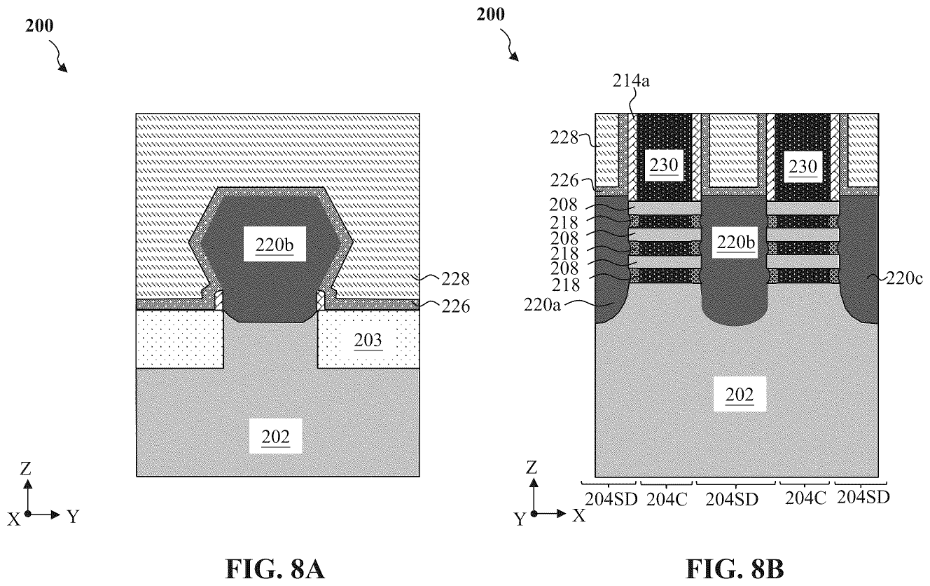

The structure 200 also includes dummy gate structures 210. Each of the dummy gate structures 210 includes a dummy gate dielectric layer 211, a dummy gate electrode layer 212 over the dummy gate dielectric layer 211, and a gate-top hard mask layer 213 over the dummy gate electrode layer 212. The dummy gate dielectric layer 211 may include silicon oxide. The dummy gate electrode layer 212 may include polysilicon. The gate-top hard mask layer 213 may include silicon oxide layer, silicon nitride, and/or other suitable materials. Suitable deposition process, photolithography and etching process may be employed to form the dummy gate structures 210. In this embodiment, a gate replacement process (or gate-last process) is adopted where the dummy gate structures 210 serve as placeholders for functional gate stacks (e.g., metal gate stacks 230 shown in FIGS. 8A-8B). Other processes and configurations are possible. Three dummy gate structures 210 are shown in FIG. 2, but the structure 200 may include any suitable number of dummy gate structures 210.

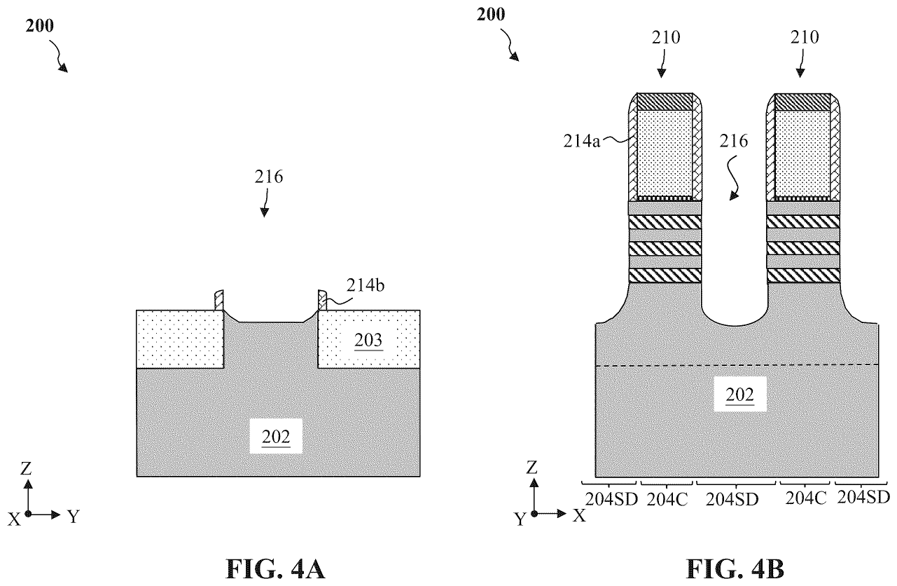

Referring to FIGS. 1 and 4A-4B, method 100 includes a block 104 where source/drain regions 204SD of the fin-shaped active regions 204 are recessed to form source/drain openings 216. In an embodiment, before forming the source/drain openings 216, a spacer layer is comfortably deposited over the structure 200 and then etched back to form gate spacers 214a extending along sidewall surfaces of the dummy gate structures 210 and fin sidewall spacers 212b adjacent to the fin-shaped active regions 204. The spacer layer may be a single-layer structure or a multi-layer structure and may be conformally deposited over the structure 200 by atomic layer deposition (ALD), chemical vapor deposition (CVD), or any other suitable deposition process. The term “conformally” may be used herein for ease of description of a layer having substantially uniform thickness over various regions of the structure 200. The spacer layer may include silicon oxide, silicon nitride, silicon oxycarbide, silicon oxycarbonitride, silicon carbonitride, metal nitride, or other suitable dielectric materials.

After forming the gate spacers 214a, the source/drain regions 204SD of the fin-shaped active regions 204 are removed to form source/drain openings 216. In an embodiment, the source/drain regions 204SD of the fin-shaped active regions 204 are anisotropically etched by a plasma etch with a suitable etchant, such as fluorine-containing etchant, oxygen-containing etchant, hydrogen-containing etchant, a fluorine-containing etchant (e.g., CF₄, SF₆, CH₂F₂, CHF₃, and/or C₂F₆), a chlorine-containing etchant (e.g., Cl₂, CHCl₃, CCl₄, and/or BCl₃), a bromine-containing etchant (e.g., HBr and/or CHBr₃), an iodine-containing etchant, other suitable etchants, and/or combinations thereof. In the present embodiments, the source/drain openings 216 extend into the mesa structure 202t of the substrate 202.

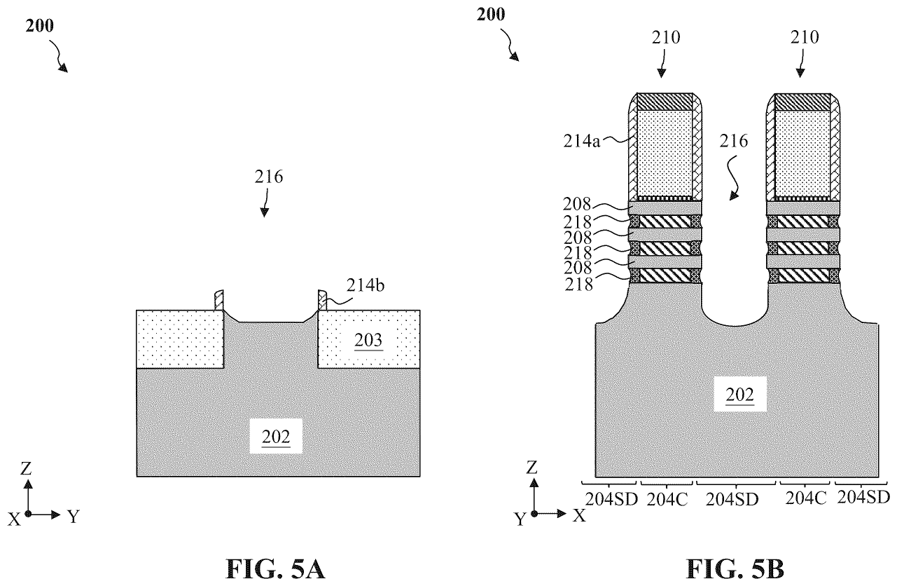

Referring to FIGS. 1 and 5A-5B, method 100 includes a block 106 where inner spacer features 218 are formed. After forming the source/drain openings 216, the sacrificial layers 206 exposed in the source/drain openings 216 are selectively and partially recessed to form inner spacer recesses (filled by inner spacer features 218), while the exposed channel layers 208 are substantially unetched. This selective recess may include a selective isotropic etching process (e.g., a selective dry etching process or a selective wet etching process), and the extent at which the sacrificial layers 206 is recessed may be controlled by duration of the etching process. After the formation of the inner spacer recesses, an inner spacer material layer is then conformally deposited using CVD or ALD over the structure 200, including over and into the inner spacer recesses. The inner spacer material may include silicon nitride, silicon oxycarbonitride, silicon carbonitride, silicon oxide, silicon oxycarbide, silicon carbide, or silicon oxynitride. The inner spacer material layer is then etched back to form the inner spacer features 218, as illustrated in FIG. 5B. In some embodiments, a composition of the inner spacer features 218 is different than a composition of the gate spacers 214a such that the etching back of the inner spacer material layer does not substantially etch the gate spacers 214a.

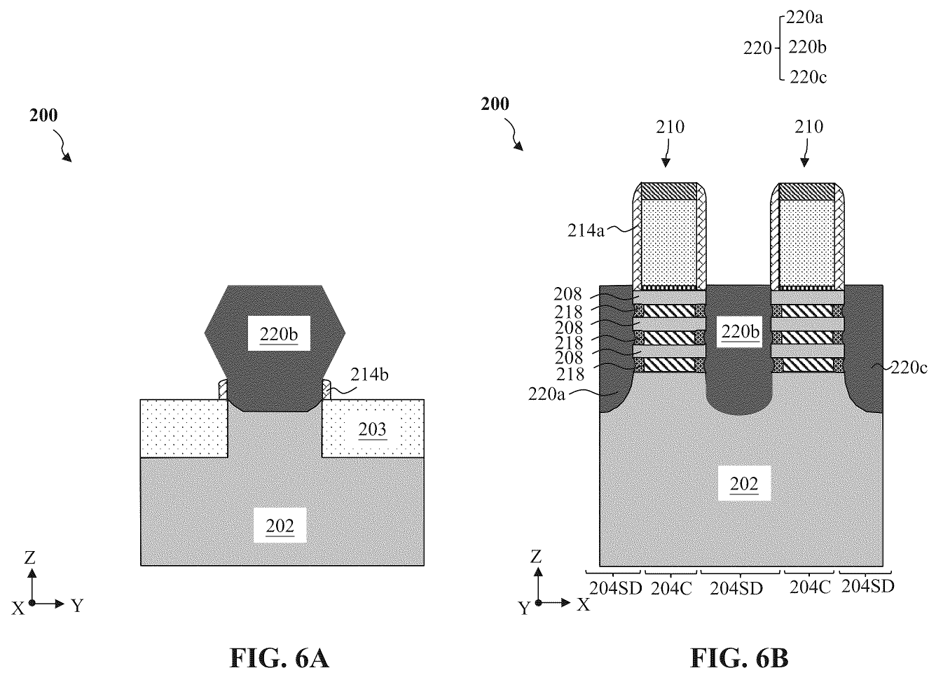

Referring now to FIGS. 1 and 6A-6B, method 100 includes a block 108 where source/drain (S/D) features (e.g., source/drain features 220a, 220b, 220c shown in FIG. 6B) are formed in the source/drain openings 216. The source/drain feature 220a, source/drain feature 220b, and source/drain feature 220c may be individually or collectively referred to as a source/drain feature 220 or source/drain features 220. Source/drain feature(s) 220 may refer to a source or a drain, individually or collectively dependent upon the context. The source/drain features 220 are coupled to the channel layers 208 of the channel regions 204C and each may be epitaxially and selectively formed from exposed sidewalls of the channel layers 208 by using an epitaxial process, such as vapor phase epitaxy (VPE), ultrahigh vacuum chemical vapor deposition (UHV-CVD), molecular-beam epitaxy (MBE), and/or other suitable processes. Example N-type source/drain features 220 may include silicon, phosphorus-doped silicon, arsenic-doped silicon, antimony-doped silicon, or other suitable material and may be in-situ doped during the epitaxial process by introducing an N-type dopant, such as phosphorus, arsenic, or antimony, or ex-situ doped using a junction implant process. Example P-type source/drain features 220 may include germanium, gallium-doped silicon germanium, boron-doped silicon germanium, or other suitable material and may be in-situ doped during the epitaxial process by introducing a P-type dopant, such as boron or gallium, or ex-situ doped using a junction implant process. In some embodiments, the source/drain feature 220 may include multiple semiconductor layers with different doping concentrations. It is noted that the profile of the source/drain feature 220b illustrated in FIG. 6A is just an example and is not intended to be limiting.

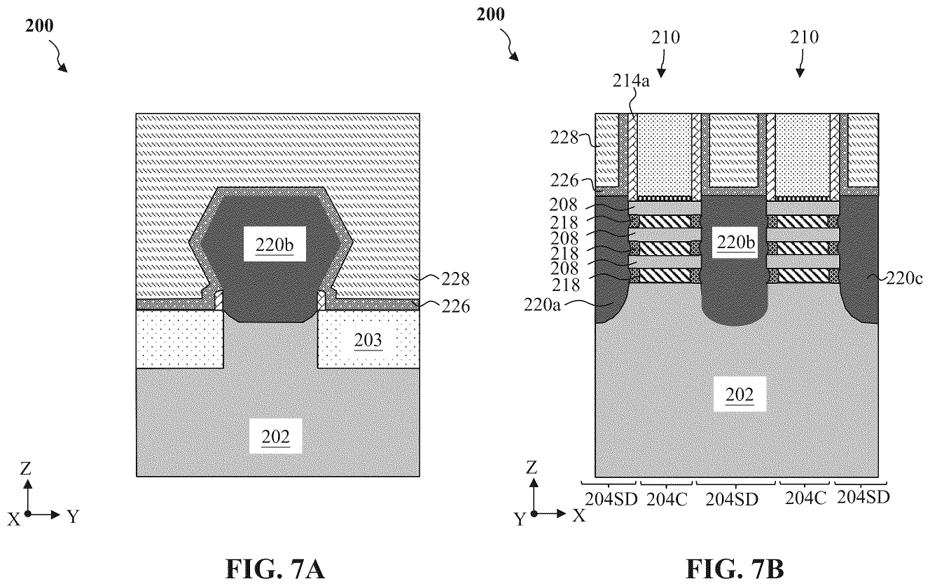

Referring now to FIGS. 1, 7A-7B, and 8A-8B, method 100 includes a block 110 where the dummy gate structures 210 and the sacrificial layers 206 are removed. With reference to FIGS. 7A-7B, after forming the source/drain features 220, a contact etch stop layer (CESL) 226 and an interlayer dielectric (ILD) layer 228 are deposited over the structure 200. The CESL 226 may include silicon nitride, silicon oxynitride, and/or other suitable materials and may be formed by ALD, plasma-enhanced chemical vapor deposition (PECVD) process and/or other suitable deposition or oxidation processes. The ILD layer 228 is deposited by, for example, a PECVD process or other suitable deposition technique over the structure 200 after the deposition of the CESL 226. The ILD layer 228 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. A planarization process, such a chemical mechanical polishing (CMP) process may be performed to the structure 200 to remove excess materials and expose top surfaces of the dummy gate electrode layers 212 in the dummy gate structures 210.

With reference to FIGS. 8A-8B, after exposing the dummy gate electrode layers 212 in the dummy gate structures 210, a first etching process may be implemented to selectively remove the dummy gate electrode layers 212 and the dummy gate dielectric layers 211 of the dummy gate structures 210 without substantially removing the gate spacers 214a to form gate trenches (now filled by metal gate stacks 230). After the removal of the dummy gate structures 210, the sacrificial layers 206 in the channel regions 204C are selectively removed to release the channel layers 208 as channel members 208. The selective removal of the sacrificial layers 206 forms gate openings (now filled by the metal gate stacks 230) under the gate trenches.

Referring now to FIGS. 1 and 8A-8B, method 100 includes a block 112 where the metal gate stacks 230 are formed in the gate trenches and openings. The formation of the metal gate stack 230 includes forming an interfacial layer to wrap around and over each of the channel members 208. The interfacial layer may include silicon oxide or other suitable material. The interfacial layer may be formed using a suitable method, such as atomic layer deposition (ALD), chemical vapor deposition (CVD), thermal oxidation, or other suitable method. In an embodiment, the interfacial layer is formed by thermal oxidation and is thus only formed on surfaces of the channel members 208. That is, the interfacial layer does not extend along sidewall surfaces of the gate spacers 214a and does not extend along sidewall surfaces of the inner spacer features 218. In another embodiment, the interfacial layer is formed by ALD and is thus conformally formed on surfaces of the structure 200. That is, the interfacial layer also extends along sidewall surfaces of the gate spacers 214a and sidewall surfaces of the inner spacer features 218. After forming the interfacial layer, a dielectric layer is formed over the structure 200 to wrap around and over each of the channel members 208. In an embodiment, the dielectric layer is deposited conformally over the structure 200. The term “conformally” may be used herein for ease of description of a layer having a substantially uniform thickness over various regions. In some embodiments, the dielectric layer is high-k dielectric layer as its dielectric constant is greater than that of silicon dioxide (˜3.9). In some implementations, the dielectric layer may include titanium oxide (TiO₂), tantalum oxide (Ta₂O₅), hafnium silicon oxide (HfSiO₄), zirconium oxide (ZrO₂), zirconium silicon oxide (ZrSiO₂), aluminum oxide (Al₂O₃), zirconium oxide (ZrO), yttrium oxide (Y₂O₃), SrTiO₃ (STO), BaTiO₃ (BTO), BaZrO, aluminum silicon oxide (AlSiO), hafnium tantalum oxide (HfTaO), hafnium titanium oxide (HfTiO), (Ba,Sr)TiO₃ (BST), silicon nitride (SiN), silicon oxynitride (SiON), combinations thereof, or other suitable material. The dielectric layer and the interfacial layer may be collectively referred to as a gate dielectric layer.

The formation of each of the metal gate stacks 230 also includes forming a gate electrode over the gate dielectric layer. The gate electrode may be a multi-layer structure that includes at least one work function layer and a metal fill layer. By way of example, the at least one work function layer may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), or tantalum carbide (TaC). The metal fill layer may include aluminum (Al), tungsten (W), nickel (Ni), titanium (Ti), ruthenium (Ru), cobalt (Co), platinum (Pt), tantalum silicon nitride (TaSiN), copper (Cu), other refractory metals, or other suitable metal materials or a combination thereof and formed by ALD, physical vapor deposition (PVD), CVD, e-beam evaporation, or other suitable process. In various embodiments, a planarization process, such as a chemical mechanical polishing (CMP) process, may be performed to remove excess materials over the ILD layer 228 to provide a substantially planar top surface and facilitate the performing of further processes.

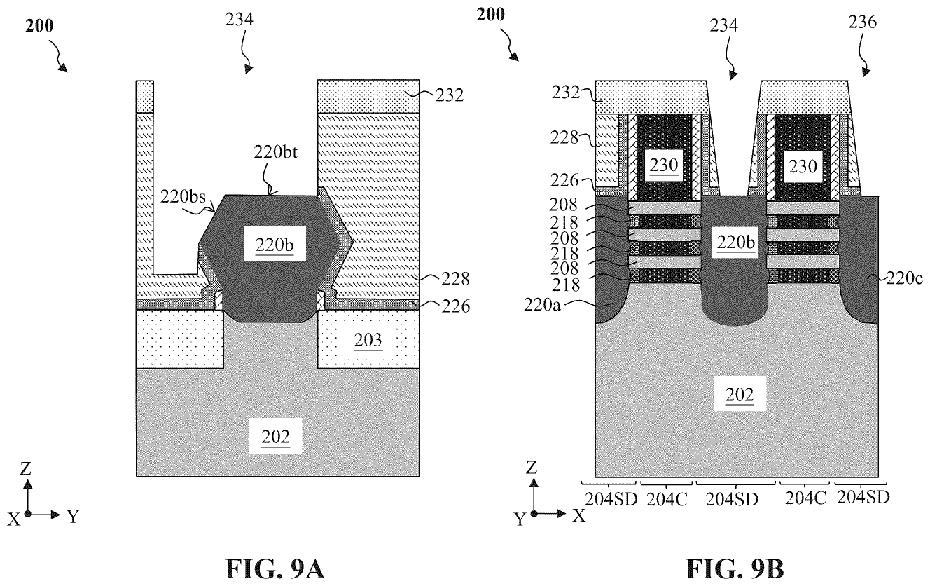

Referring to FIGS. 1 and 9A-9B, method 100 includes a block 114 where a first source/drain contact opening 234 and a second source/drain contact opening 236 are formed to expose the source/drain feature 220b and the source/drain feature 220c, respectively. In an example process, a dielectric structure 232 is formed over the ILD layer 228 and the metal gate stacks 230. The dielectric structure 232 may include an etch stop layer and a dielectric layer deposited over the etch stop layer. The etch stop layer may be similar to the CESL 226, and the dielectric layer may be similar to the ILD layer 228 in terms of compositions and formation processes. The etch stop layer in the dielectric structure 232 may indicate an etch stop point for forming gate via openings over the metal gate stacks 230.

After forming the dielectric structure 232, source/drain contact openings (e.g., the first source/drain contact opening 234 and the second source/drain contact opening 236) are formed to expose the source/drain feature 220b and the source/drain feature 220c, respectively, using a combination of photolithography processes and etch processes. In an example process, a hard mask layer and a photoresist are formed over the dielectric structure 232. The photoresist layer is then exposed to a patterned radiation transmitting through or reflected from a photo mask, baked in a post-exposure bake process, developed in a developer solution, and then rinsed, thereby forming a patterned photoresist layer. The patterned photoresist layer is then applied as an etch mask to etch the hard mask layer to form a patterned hard mask layer. While using the patterned hard mask layer as an etch mask, an etching process is performed to selectively etch the dielectric structure 232, the ILD layer 228, and the CESL 226 without substantially etching the source/drain features 220 to form the first source/drain contact opening 234 and the second source/drain contact opening 236. The etching process for etching the dielectric structure 232, the ILD layer 228, and the CESL 226 may be a dry etch process that includes use of argon (Ar), a fluorine-containing etchant (for example, SF₆, NF₃, CH₂F₂, CHF₃, C₄F₈, and/or C₂F₆), an oxygen-containing etchant, a chlorine-containing etchant (for example, Cl₂, CHCl₃, CCl₄, and/or BCl₃), a bromine-containing etchant (for example, HBr and/or CHBr₃), an iodine-containing etchant, or combinations thereof. In this embodiment, the first source/drain contact opening 234 exposes not only at least a portion of a top surface 220bt of the source/drain feature 220b that faces up, but also exposes a portion of a sidewall surface 220bs of the source/drain feature 220b. In this illustrated embodiment, as represent by FIG. 9A, after the performing of the etching process, the first source/drain contact opening 234 does not expose a top surface of the STI feature 203. The depth of the first source/drain contact opening 234 may be controlled by adjusting a duration of the etching process. For embodiments in which the etching process is performed for a longer duration, the first source/drain contact opening 234 may expose or even extend into the STI feature 203. Although not shown, the second source/drain contact opening 236 may or may not expose a sidewall surface of the source/drain feature 220c when viewed from the X direction.

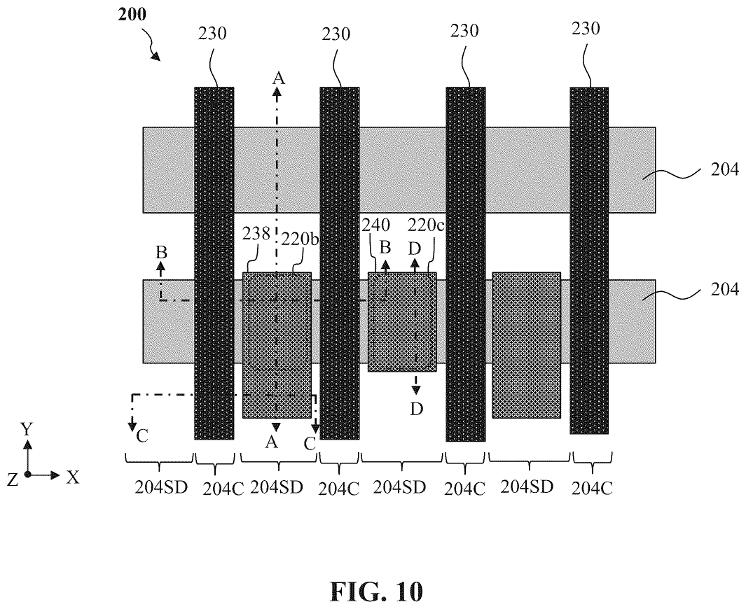

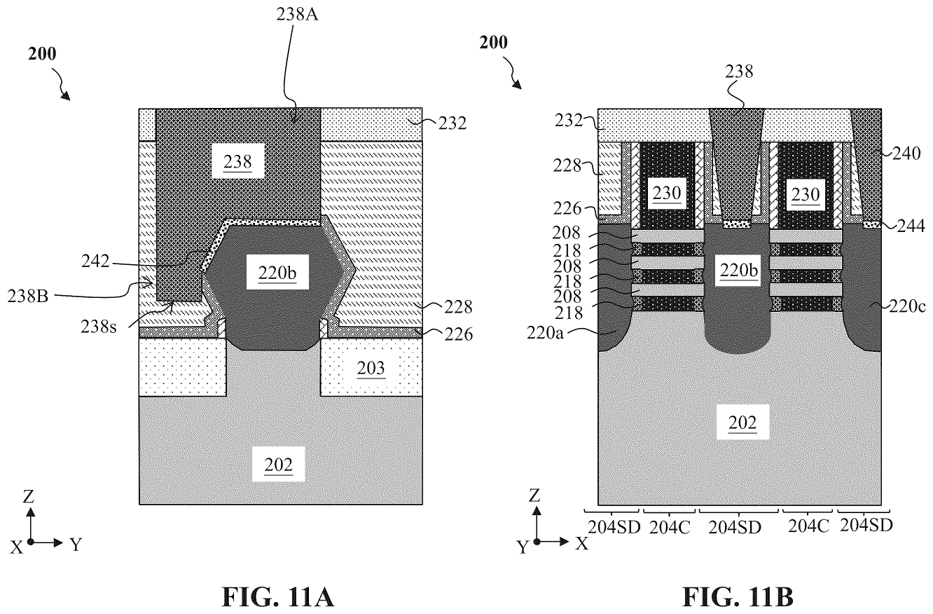

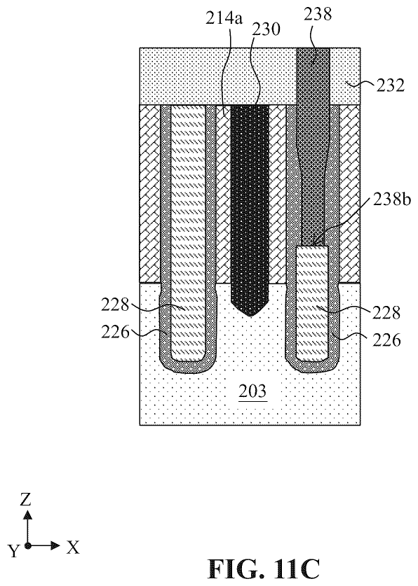

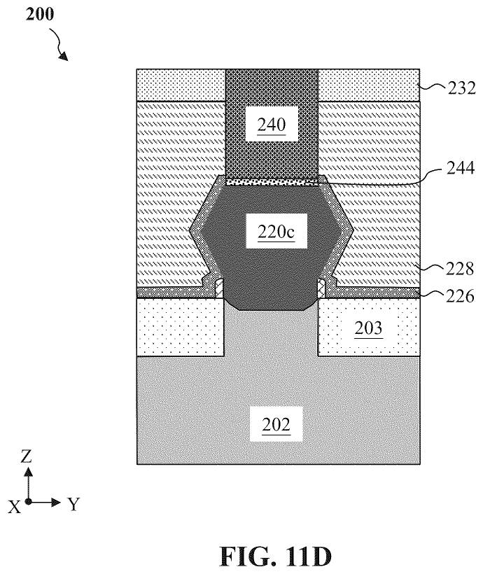

Referring to FIGS. 1, 10, and 11A-11D, method 100 includes a block 116 where a first source/drain contact 238 and a second source/drain contact 240 are formed in the first and second source/drain contact openings 234 and 236, respectively. FIGS. 11A, 11B, 11C, and 11D depict cross-sectional views of the structure 200 taken along line A-A, line B-B, line C-C, and line D-D as shown in FIG. 10, respectively. It is noted that some features are omitted in FIG. 10 for reason of simplicity. After forming the source/drain contact openings (e.g., the first source/drain contact opening 234, the second source/drain contact opening 236), with respect to FIGS. 11A-11D, silicide layers (e.g., silicide layers 242, 244) are formed in the source/drain contact openings. To form the silicide layers 242 and 244, a metal precursor (e.g., titanium, tantalum, nickel, cobalt, or tungsten) is deposited over the structure 200, including on the exposed surface of the n-type source/drain feature 222N and the exposed surfaces of the source/drain features 220b-220c. An anneal process is then performed to bring about silicidation or germinidation between the metal precursor and the exposed surfaces of the source/drain features 220b-220c. The unreacted metal precursor is selectively removed after the formation of the silicide layers 242 and 244.

A conductive layer is then deposited over the structure 200, including in the first and second source/drain contact openings 234 and 236 and on the silicide layers 242 and 244. The conductive layer may include aluminum (Al), copper (Cu), tungsten (W), cobalt (Co), ruthenium (Ru), or molybdenum (Mo) or other suitable materials and may be formed by any suitable deposition processes (e.g., CVD). A planarization process, such as a chemical mechanical polish (CMP) process, may be then performed to remove excess portions of the conductive layer to form the first source/drain contact 238 and the second source/drain contact 240 in the first and second source/drain contact openings 234 and 236, respectively. After the performing of the planarization process, top surfaces of the first and second source/drain contacts 238 and 240 are coplanar with the dielectric structure 232.

As represented by FIG. 11A, the first source/drain contact 238 includes a portion 238A disposed directly over the source/drain feature 220b and a portion 238B disposed laterally adjacent to the source/drain feature 220b. In this embodiment, a bottommost surface 238s of the first source/drain contact 238 is above the top surface of the STI feature 203. Although not shown, in some embodiments, barrier layers may be formed to extend along sidewall surfaces of the first and second source/drain contacts 238 and 240. In the embodiment represented by FIG. 11D, an entirety of the second source/drain contact 240 is disposed over the source/drain feature 220c. In some other alternative embodiments, a portion of the second source/drain contact 240 may also below a top surface of the source/drain feature 220c. In the embodiment represented by FIG. 10, a length of the first source/drain contact 238 along the Y direction is greater than a length of the second source/drain contact 240 along the Y direction.

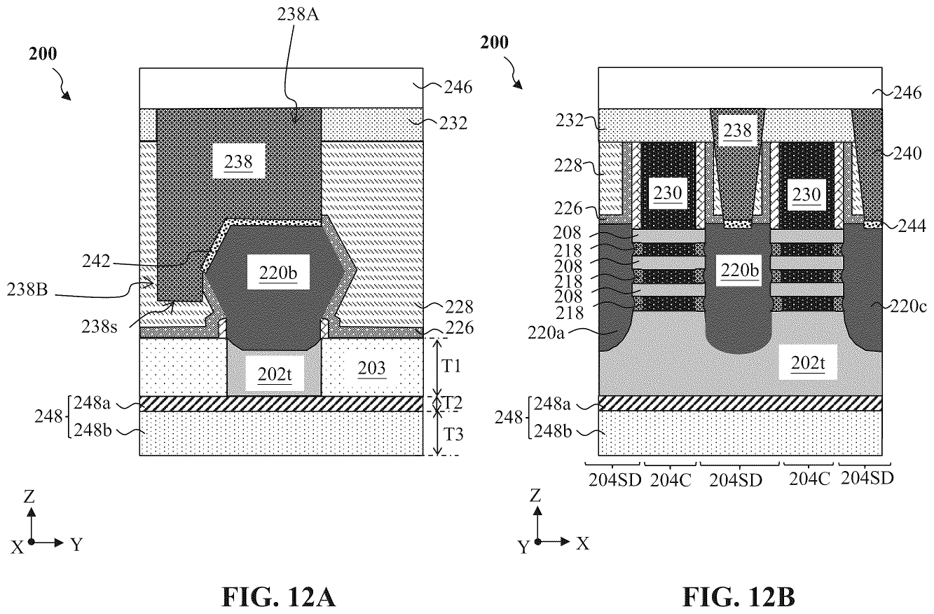

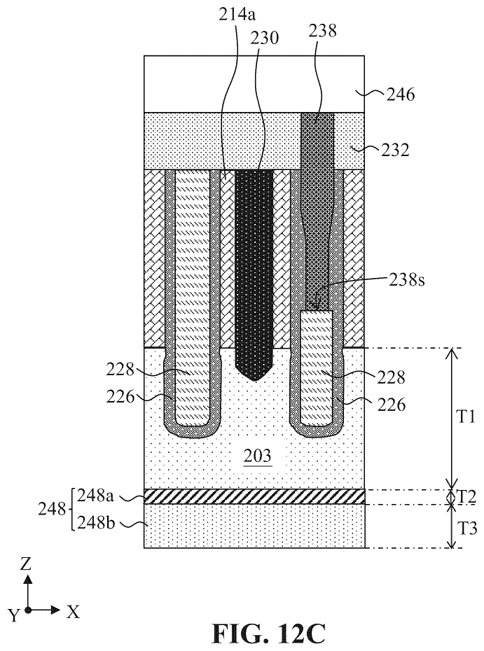

Referring to FIGS. 1 and 12A-12C, method 100 includes a block 118 where a thickness of the substrate 202 is reduced from its back. After forming the silicide layers 242-244 and the first and second source/drain contacts 238 and 240, other features such as gate vias and an interconnect structure 246 may be formed over the structure 200. In some embodiments, the interconnect structure 246 may include multiple intermetal dielectric (IMD) layers and multiple metal lines or contact vias in each of the IMD layers. In some instances, the IMD layers and the ILD layer 228 may share similar composition. The metal lines and contact vias in each IMD layer may be formed of metal, such as aluminum, tungsten, ruthenium, or copper. In some embodiments, the metal lines and contact vias may be lined by a barrier layer to reduce electro-migration. Because the interconnect structure 246 is formed over the front side of the structure 200, the interconnect structure 246 may also be referred to as a frontside interconnect structure 246.

A carrier substrate (not shown) is then bonded to the interconnect structure 246 by fusion bonding, by use of an adhesion layer, or a combination thereof. In some instances, the carrier substrate may include semiconductor materials (such as silicon), sapphire, glass, polymeric materials, or other suitable materials. In embodiments where fusion bonding is used, the carrier substrate includes a bottom oxide layer and the interconnect structure 246 includes a top oxide layer. After both the bottom oxide layer and top oxide layer are treated, they are placed in plush contact with one another for direct bonding at room temperature or at an elevated temperature. Once the carrier substrate is bonded to the interconnect structure 246 of the structure 200, the structure 200 is flipped over. The back side of the structure 200 is then planarized (e.g., by a planarization process such as a chemical mechanical poshing CMP process) to reduce a thickness of the substrate 202 from its back. In an embodiment, as depicted by FIGS. 12A-12C, the planarization process may stop after the bottom surface of the STI feature 203 and the mesa structure 202t being exposed. In some embodiments, the planarization process may also remove a portion of the STI feature 203. For ease of description, positional relationships hereafter will be described based on the structure 200 before the flipping, as depicted in the figures. In an embodiment, after performing the planarization process, a thickness T1 of the STI feature 203 (and thus a thickness of the substrate 202) is in a range between about 10 nm and about 50 nm. If the thickness T1 is greater than 50 nm, fabrication difficulty (e.g., performing satisfactory deposition processes for forming a deep backside via) may be increased, and device performance may be adversely impacted due to high parasitic resistance and parasitic capacitance associated with the deep backside via. If the thickness T1 is less than 50 nm, backside features (e.g., backside via 260, backside metal line 264) may contact frontside features (e.g., metal gate stack 230), leading to leakage current or device failure.

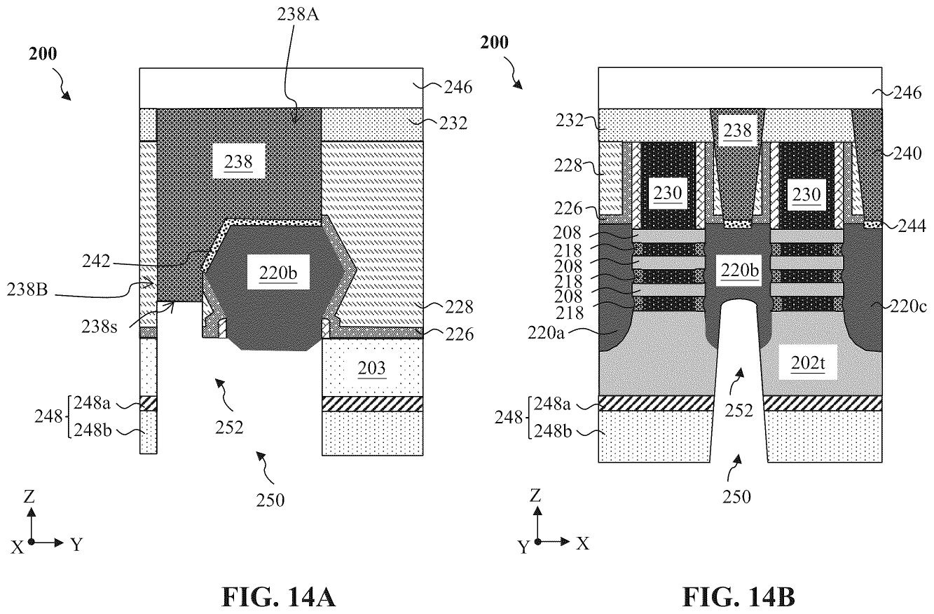

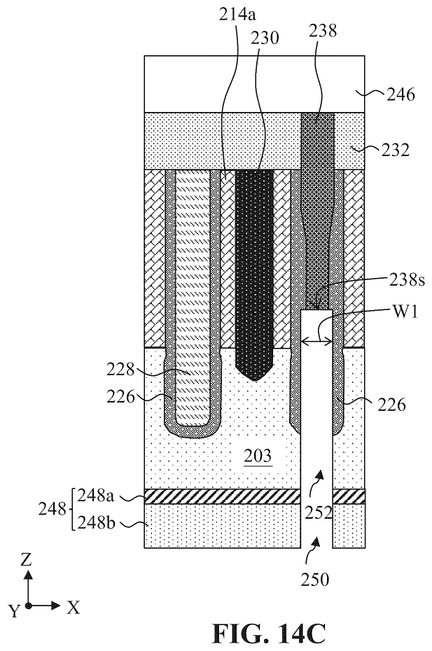

Referring to FIGS. 1, 12A-12C and 13A-13C, method 100 includes a block 120 where a patterned dielectric structure 248 is formed under the substrate 202. With reference to FIGS. 12A-12C, a dielectric structure 248 is formed under the bottom surface of the planarized structure 200. In the present embodiment, to provide an end point for a subsequent planarization process, the dielectric structure 248 includes a first layer 248a and a second layer 248b having a material composition different than the first layer 248a. In an embodiment, the first layer 248a includes a nitride layer (e.g., silicon nitride), and the second layer 248b includes an oxide layer (e.g., silicon oxide). A thickness T2 of the first layer 248a may be in a range between about 5 nm and about 15 nm. If the thickness T2 is less than 5 nm, the first layer 248a may not be able to provide satisfactory isolation to prevent unwanted electrical connection between the frontside features (e.g., metal gate stack 230) and backside features (e.g., backside via 260, backside metal line 264); if the thickness T2 is greater than 15 nm, it would increase fabrication difficulty for forming a satisfactory backside via. For example, a thick first layer may lead to a longer etch duration for forming backside via opening (e.g., trench 252 shown in FIGS. 14A-14C), a deeper backside via opening, and thus an increased deposition difficulty for forming layers in the deep backside via opening. A thickness T3 of the second layer 248b may be in a range between about 15 nm and 45 nm to facilitate the patterning of the dielectric structure 248 and the controlling of the planarization end point associated with the formation of the backside via 260.

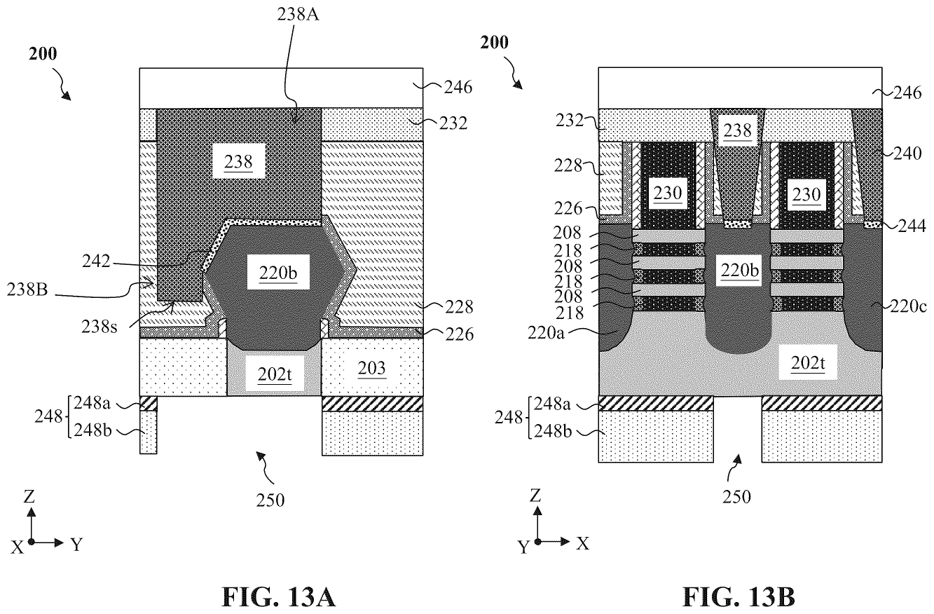

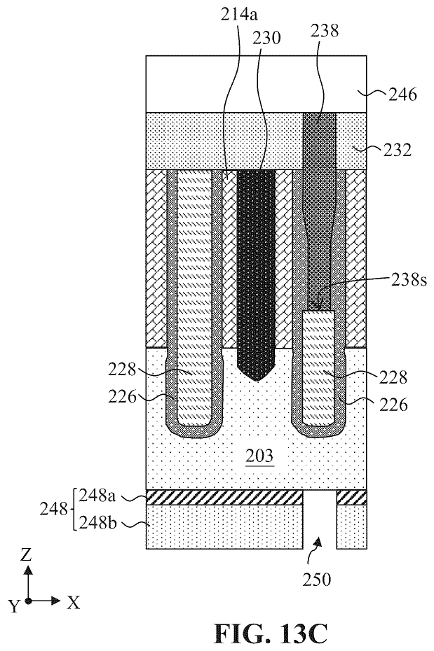

With reference to FIGS. 13A-13C, the dielectric structure 248 is patterned to form an opening 250. The opening 250 exposes the mesa structure 202t and a portion of the STI feature 203. In the present embodiments, the opening 250 is disposed directly under at least a part of the source/drain feature 220b and at least a part of the portion 238B of the first source/drain contact 238.

Referring to FIGS. 1 and 14A-14C, method 100 includes a block 122 where a trench 252 is formed under the structure 200. While using the patterned dielectric structure 248 as an etch mask, an etching process is performed to remove the portion of the dielectric features (e.g., CESL 226, ILD layer 228, STI feature 203) disposed directly under the portion 238B of the first source/drain contact 238 and at least a portion of the mesa structure 202t disposed directly under the source/drain feature 220b to form the trench 252. The etching process may be selective wet etching process or a selective dry etching process. In some embodiments, the etching process may etch dielectric features (e.g., the STI feature 203, the CESL 226, and the ILD layer 228) and semiconductor features (e.g., the mesa structure 202t, the source/drain feature 220b) at different etch rates. As illustrated by FIG. 14A, upon completion of the etching process, the trench 252 exposes the bottommost surface 238s of the first source/drain contact 238 and the source/drain feature 220b. In the cross-sectional view represented by FIG. 14B, the trench 252 also extends into the source/drain feature 220b. In the cross-sectional view represented by FIG. 14C, the trench 252 spans a width W1 along the X direction. In an embodiment, the width W1 is in a range between about 5 nm and about 20 nm. If the width W1 is greater than 20 nm, the trench 252 may expose a portion of the metal gate stack 230, leading to unwanted electrical connection between the metal gate stack 230 and the backside via 260 formed in the trench 252; if the width W1 is less than 5 nm, the backside via 260 formed in the trench 252 may induce high parasitic resistance.

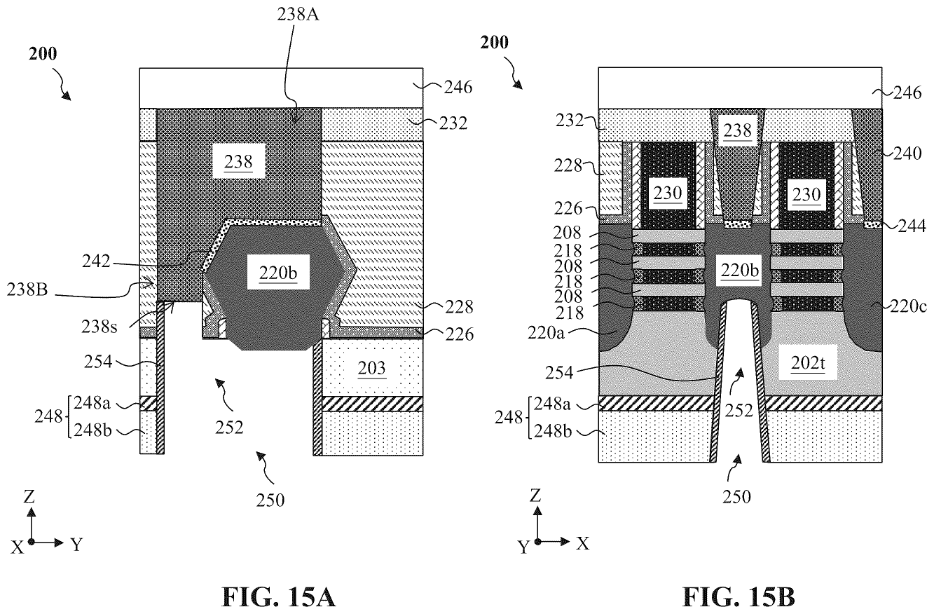

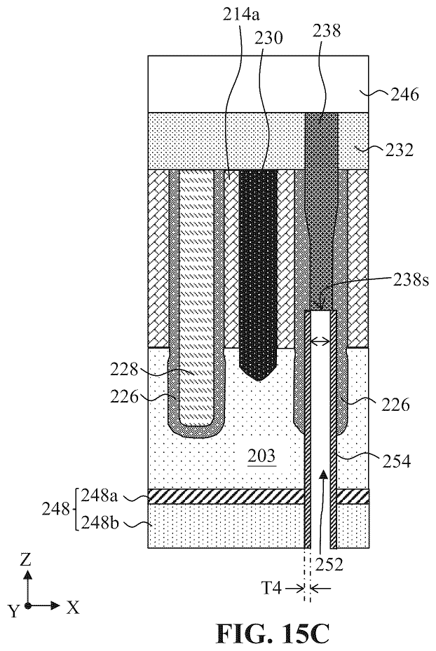

Referring to FIGS. 1 and 15A-15C, method 100 includes a block 124 where a dielectric liner 254 is formed in the trench 252. After the formation of the trench 252, in the present embodiments, to prevent surfaces of the substrate 202 exposed by the trench 252 from subsequent silicidation process and to provide isolation between the backside via 260 and the substrate 202, a dielectric liner 254 is formed to extend along a sidewall surface of the trench 252. In an example process, a dielectric layer is conformally deposited under the structure 200 and in the trench 252 and is then etched back to only keep portions that extend along sidewall surface of the trench 252, thereby forming the dielectric liner 254. In some embodiments, the dielectric liner 254 may include silicon nitride, silicon oxide, or other suitable materials. The dielectric liner 254 has a thickness T4. In an embodiment, the thickness T4 is in a range between about 1 nm and about 2.5 nm. If the thickness T1 is greater than 2.5 nm, the spacing for forming backside via may be too small, increasing deposition difficulty and increase parasitic resistance; if the thickness T4 is less than 1 nm, the thin dielectric liner 254 may be damaged during subsequent fabrication processes, leading to poor electrical isolation between the backside via 260 and the substrate 202.

Referring to FIGS. 1, 16A-16C, and 17, method 100 includes a block 126 where a conductive layer 256 and a backside via 260 are formed in the trench 252. After forming the trench 252, a metal precursor (e.g., titanium, tantalum, nickel, cobalt, or tungsten) is deposited under the structure 200, including on the surface of the source/drain feature 220b and the bottommost surface 238s of the first source/drain contact 238 exposed by the trench 252. An anneal process is then performed to bring about silicidation or germinidation between the metal precursor and the exposed surfaces of the source/drain features 220b to form a silicide layer 256a in the trench 252. The unreacted metal precursor is selectively removed after the formation of the silicide layer 256a (e.g., titanium silicide, nickel silicide, cobalt silicide). In an embodiment, a thickness T5 of the silicide layer 256a is in a range between about 5 nm and about 10 nm. A portion of the metal precursor is in direct contact with the first source/drain contact 238 exposed by the trench 252. In some embodiments, during the anneal process, this portion of the metal precursor may react with ambient element(s) to form a compound layer 256b. For example, in embodiments where the metal precursor includes titanium, the compound layer 256b may include titanium nitride (TiN). A thickness T6 of the compound layer 256b is less than the thickness T5 of the silicide layer 256a. In an embodiment, the thickness T6 is in a range between about 0.5 nm and about 3 nm. The silicide layer 256a and the compound layer 256b may be regarded as portions of a conductive layer 256.

A conductive material layer 258 is then deposited over the back side of structure 200, including in the trench 252 and on the conductive layer 256. The conductive material layer 258 may include titanium nitride (TiN), titanium (Ti), copper (Cu), tungsten (W), cobalt (Co), ruthenium (Ru), molybdenum (Mo), other suitable materials, or combinations thereof, and may be formed by any suitable deposition processes (e.g., CVD). A planarization process, such as a chemical mechanical polish (CMP) process, may be then performed to remove excess materials under the first layer 248a of the dielectric structure 248, including the second layer 248b, to define a final structure of the backside via 260. A bottom surface of the backside via 260 is coplanar with a bottom surface of the first layer 248a of the dielectric structure 248. The backside via 260 includes both the compound layer 256b and the portion of the conductive material layer 258 formed in the trench 252. FIG. 17 depicts a fragmentary perspective view of the structure 200. It is noted that some features (e.g., silicide layers) are omitted for reason of simplicity. By directly contacting the backside via 260 with the frontside source/drain contact 238, as represented by the dashed line 261 and arrows, power signal may be provided to the source/drain feature 220b from its back side and its front side.

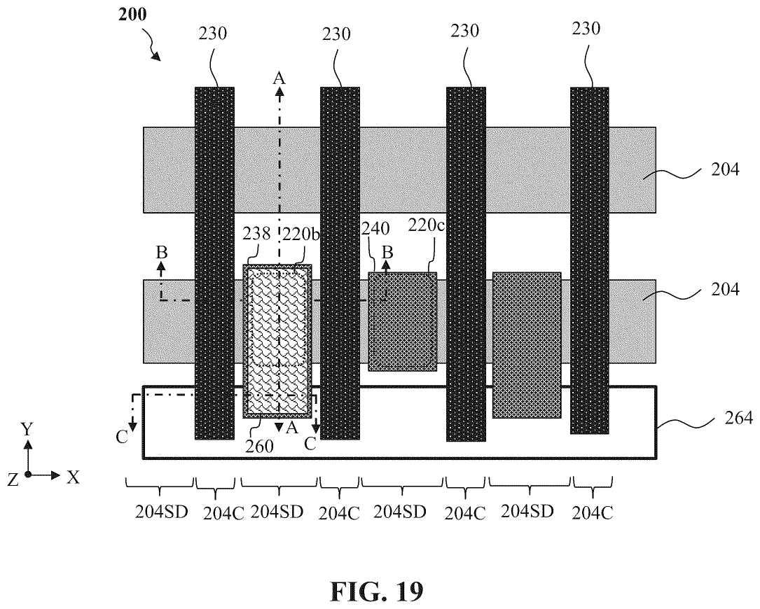

Referring to FIGS. 1, 18A-18C, and 19, method 100 includes a block 128 where further processes are performed. Such further processes may include forming an interconnect structure 262 under the backside via 260. In some embodiments, the interconnect structure 262 may include a multiple intermetal dielectric (IMD) layers and multiple metal lines (e.g., metal line 264 shown in FIG. 19) or contact vias in each of the IMD layers. In some instances, the IMD layers and the ILD layer 228 may share similar composition. The metal lines and contact vias in each IMD layer may be formed of metal, such as aluminum, tungsten, ruthenium, or copper. In some embodiments, the metal lines and contact vias may be lined by a barrier layer to reduce electro-migration. Because the interconnect structure 262 is formed under the back side of the structure 200, the interconnect structure 262 may also be referred to as a backside interconnect structure 262. In an embodiment, the metal line 264 of the backside interconnect structure 262 is disposed under and in direct contact with the backside via 260. As illustrated in FIG. 19, the metal line 264 extends lengthwise along the X direction. It is noted that, in this illustrated example, the second source/drain contact 240 is not vertically overlapped with the metal line 264. In an embodiment, when viewed from top, the source/drain contact 238 has a larger area than the backside via 260.

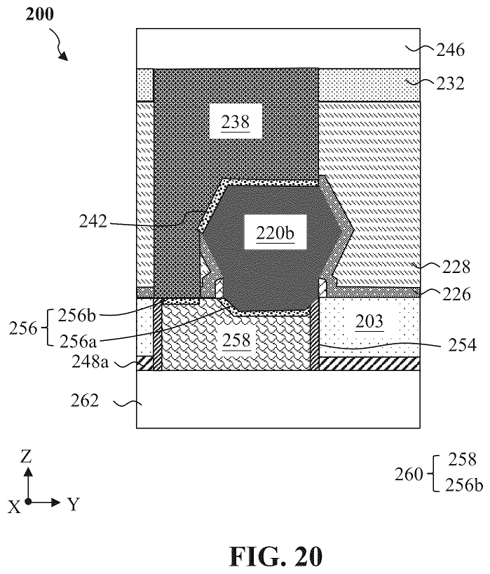

In the above embodiments, the backside via 260 extends into the ILD layer 228 from its back side. In some alternative embodiments, as described above with reference to FIGS. 9A-9B, the duration of the etching process for forming the first source/drain contact opening 234 may be adjusted. For embodiments in which the etching process is performed for a longer duration, the first source/drain contact opening 234 may expose or even extend into the STI feature 203. Similarly, to expose the bottommost surface 238s of the first source/drain contact 238, the duration of the etching process for forming the trench 252 (shown in FIGS. 15A-15C) may be adjusted accordingly. FIG. 20 depicts a fragmentary cross-sectional view of an alternative embodiment of the structure 200. In this illustrated alternative embodiment, the first source/drain contact 238 extends through both the ILD layer 228 and the CESL 226, and the backside via 260 extends through the first layer 248a and the STI feature 203. That is, an interface between the first source/drain contact 238 and the backside via 260 is coplanar with a top surface of the STI feature 203. In some other alternative embodiments, the interface may be under the top surface of the STI feature 203.

Although not intended to be limiting, one or more embodiments of the present disclosure provide many benefits to a semiconductor structure and the formation thereof. For example, a backside source/drain via formed under a source/drain feature is in direct contact with a frontside source/drain contact formed directly over the source/drain feature to achieve dual side power delivery with enhanced power delivery efficiency, improved device performance (e.g., improved speed), and reduced fabrication difficulty and cost.

The present disclosure provides for many different embodiments. Semiconductor structures and methods of fabrication thereof are disclosed herein. In one exemplary aspect, the present disclosure is directed to a method. The method includes receiving a workpiece comprising a plurality of nanostructures over a substrate, a gate stack wrapping around and over the plurality of nanostructures, and a source/drain feature coupled to the plurality of nanostructures. The method also includes forming a dielectric structure over the workpiece, forming a first opening in the dielectric structure to expose the source/drain feature, forming a source/drain contact in the first opening, and forming a backside via disposed under the source/drain feature, the backside via is electrically coupled to the source/drain feature and adjacent to the source/drain contact.

In some embodiments, the first opening may expose a top surface and a portion of a sidewall surface of the source/drain feature. In some embodiments, the method may also include, after the forming of the first opening, forming a silicide layer on the top surface and the portion of the sidewall surface of the source/drain feature. In some embodiments, the forming of the backside via may include reducing a thickness of the substrate from its back side, forming another dielectric structure under the substrate, patterning the another dielectric structure to form a second opening exposing a bottom surface of the source/drain feature and a portion of the source/drain contact, and forming the backside via in the second opening. In some embodiments, the another dielectric structure may include a first dielectric layer under a back side of the substrate, and a second dielectric layer under the first dielectric layer, the first dielectric layer has a material composition different than the second dielectric layer. In some embodiments, the forming of the backside via may also include after the forming of the second opening, forming a dielectric liner extending along a sidewall of the second opening, forming a compound layer in the second opening, wherein the compound layer includes a first portion in direct contact with the source/drain feature and a second portion in direct contact with the source/drain contact, forming a conductive layer in the second opening, and performing a planarization process to remove the second dielectric layer. In some embodiments, the second portion may have a material composition different than the first portion. In some embodiments, a portion of the backside via may extend into the source/drain feature. In some embodiments, when viewed from top, the source/drain contact and the gate stack may extend lengthwise along a same direction. In some embodiments, the workpiece may also include an isolation feature over the substrate and adjacent to a portion of the substrate disposed directly under the plurality of nanostructures, at least one of the source/drain contact and the backside via may extend into the isolation feature.

In another exemplary aspect, the present disclosure is directed to a method. The method includes forming a source/drain feature over a substrate, forming a first conductive feature over the source/drain feature, wherein the first conductive feature comprises a first portion disposed directly over the source/drain feature and a second portion disposed adjacent to the source/drain feature, and forming a second conductive feature disposed under and electrically coupled to the source/drain feature, wherein the second conductive feature is in direct contact with the second portion of the first conductive feature.

In some embodiments, the method may also include forming a dielectric structure over the source/drain feature, the dielectric structure comprising a first portion disposed directly over the source/drain feature and a second portion adjacent to the source/drain feature. The forming of the first conductive feature may include removing a part of the first portion and a part of the second portion to form a contact opening exposing the source/drain feature, forming a first silicide layer in the contact opening, and forming a conductive layer in the contact opening. In some embodiments, the dielectric structure is a first dielectric structure, and the forming of the second conductive feature may include forming a second dielectric structure under the substrate, patterning the second dielectric structure to form an opening, the opening exposing a portion of the substrate disposed under the source/drain feature and a portion of an isolation feature adjacent to the portion of the substrate, removing the portion of the substrate, the portion of the isolation feature, and a portion of the first dielectric structure between the isolation feature and the first conductive feature, thereby forming a via opening, forming a dielectric liner in the via opening, depositing a conducive material layer to fill the via opening, and performing a planarization process. In some embodiments, the method may also include forming a metal line under and in direct contact with the second conductive feature, the first conductive feature extends lengthwise along a first direction, and the metal line extends lengthwise along a second direction substantially perpendicular to the first direction. In some embodiments, the source/drain feature is a first source/drain feature, and the method may also include forming a second source/drain feature over the substrate and forming a third conductive feature directly over and electrically coupled to the second source/drain feature, when viewed from top, a length of the first conductive feature is greater than a length of the third conductive feature. In some embodiments, a bottommost surface of the third conductive feature may be above a bottommost surface of the first conductive feature.

In yet another exemplary aspect, the present disclosure is directed to a semiconductor structure. The semiconductor structure includes a gate stack wrapping around a plurality of nanostructures disposed over a substrate, a source/drain feature coupled to the plurality of nanostructures and adjacent to the gate stack, a source/drain contact disposed over and electrically coupled to the source/drain feature, and a via disposed under and electrically coupled to the source/drain feature, wherein the via is in direct contact with the source/drain contact.

In some embodiments, the semiconductor structure may also include a dielectric liner providing isolation between the substrate and the via. In some embodiments, the semiconductor structure may also include a first silicide layer disposed between the source/drain contact and the source/drain feature and a second silicide layer disposed between the via and the source/drain feature. In some embodiments, the semiconductor structure may also include a dielectric structure over the source/drain feature, where the via extends into the dielectric structure from its back side.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
receiving a workpiece comprising:
a plurality of nanostructures over a substrate,
a gate stack wrapping around and over the plurality of nanostructures, and
a source/drain feature coupled to the plurality of nanostructures;
forming a dielectric structure over the workpiece;
forming a first opening in the dielectric structure to expose the source/drain feature;
forming a source/drain contact in the first opening; and
forming a backside via disposed under the source/drain feature, wherein the backside via is electrically coupled to the source/drain feature and adjacent to the source/drain contact.

2. The method of claim 1, wherein the first opening exposes a top surface and a portion of a sidewall surface of the source/drain feature.

3. The method of claim 2, further comprising:
after the forming of the first opening, forming a silicide layer on the top surface and the portion of the sidewall surface of the source/drain feature.

4. The method of claim 1, wherein the forming of the backside via comprises:
reducing a thickness of the substrate from its back side;
forming another dielectric structure under the substrate;
patterning the another dielectric structure to form a second opening exposing a bottom surface of the source/drain feature and a portion of the source/drain contact; and
forming the backside via in the second opening.

5. The method of claim 4, wherein the another dielectric structure comprises:
a first dielectric layer under a back side of the substrate; and
a second dielectric layer under the first dielectric layer, wherein the first dielectric layer has a material composition different than the second dielectric layer.

6. The method of claim 5, wherein the forming of the backside via further comprises:
after the forming of the second opening, forming a dielectric liner extending along a sidewall of the second opening;
forming a compound layer in the second opening, wherein the compound layer includes a first portion in direct contact with the source/drain feature and a second portion in direct contact with the source/drain contact;
forming a conductive layer in the second opening; and
performing a planarization process to remove the second dielectric layer.

7. The method of claim 6, wherein the second portion has a material composition different than the first portion.

8. The method of claim 1, wherein a portion of the backside via extends into the source/drain feature.

9. The method of claim 1, wherein, when viewed from top, the source/drain contact and the gate stack extends lengthwise along a same direction.

10. The method of claim 1, wherein the workpiece further comprises an isolation feature over the substrate and adjacent to a portion of the substrate disposed directly under the plurality of nanostructures, wherein at least one of the source/drain contact and the backside via extend into the isolation feature.

11. A method, comprising:
forming a source/drain feature over a substrate;
forming a first conductive feature over the source/drain feature, wherein the first conductive feature comprises a first portion disposed directly over the source/drain feature and a second portion disposed adjacent to the source/drain feature; and
forming a second conductive feature disposed under and electrically coupled to the source/drain feature, wherein the second conductive feature is in direct contact with the second portion of the first conductive feature.

12. The method of claim 11, further comprising:
forming a dielectric structure over the source/drain feature, the dielectric structure comprising a first portion disposed directly over the source/drain feature and a second portion adjacent to the source/drain feature,
wherein the forming of the first conductive feature comprises:
removing a part of the first portion and a part of the second portion to form a contact opening exposing the source/drain feature;
forming a first silicide layer in the contact opening; and
forming a conductive layer in the contact opening.

13. The method of claim 12, wherein the dielectric structure is a first dielectric structure, and wherein the forming of the second conductive feature comprises:
forming a second dielectric structure under the substrate;
patterning the second dielectric structure to form an opening, the opening exposing a portion of the substrate disposed under the source/drain feature and a portion of an isolation feature adjacent to the portion of the substrate;
removing the portion of the substrate, the portion of the isolation feature, and a portion of the first dielectric structure between the isolation feature and the first conductive feature, thereby forming a via opening;
forming a dielectric liner in the via opening;
depositing a conducive material layer to fill the via opening; and
performing a planarization process.

14. The method of claim 13, further comprising:
forming a metal line under and in direct contact with the second conductive feature, wherein the first conductive feature extends lengthwise along a first direction, and the metal line extends lengthwise along a second direction substantially perpendicular to the first direction.

15. The method of claim 11, wherein the source/drain feature is a first source/drain feature, and the method further comprises:
forming a second source/drain feature over the substrate; and
forming a third conductive feature directly over and electrically coupled to the second source/drain feature, when viewed from top, a length of the first conductive feature is greater than a length of the third conductive feature.

16. The method of claim 15, wherein a bottommost surface of the third conductive feature is above a bottommost surface of the first conductive feature.

17. A semiconductor structure, comprising:
a gate stack wrapping around a plurality of nanostructures disposed over a substrate;
a source/drain feature coupled to the plurality of nanostructures and adjacent to the gate stack;
a source/drain contact disposed over and electrically coupled to the source/drain feature; and
a via disposed under and electrically coupled to the source/drain feature, wherein the via is in direct contact with the source/drain contact.

18. The semiconductor structure of claim 17, further comprising:
a dielectric liner providing isolation between the substrate and the via.

19. The semiconductor structure of claim 17, further comprising:
a first silicide layer disposed between the source/drain contact and the source/drain feature; and
a second silicide layer disposed between the via and the source/drain feature.

20. The semiconductor structure of claim 17, further comprising:
a dielectric structure over the source/drain feature,
wherein the via extends into the dielectric structure from its back side.
